(19) United States
(12) Patent Application Publication
(10) Pub. No.: US 2011/0067626 A1
(43) Pub. Date: Mar. 24, 2011

(54) Apparatus for the fabrication of periodically poled frequency doubling crystals

(75) Inventor: Gisele Maxwell, Cottonwood, CA (US)

(73) Assignee: Shasta Crystals, Inc.

(21) Appl. No.: 12/586,439

(22) Filed: Sep. 22, 2009

(51) Int. Cl. C30B 13/00

(52) U.S. Cl. 117/204

(57) ABSTRACT

A laser heated pedestal growth system for growing a periodically poled, single crystal rod having domain interfaces substantially parallel to the rod's long axis. Suitable crystalline ferroelectric feed materials have a Curie temperature no greater than ˜200° C. below its melting point and include Lithium Niobate and MgO doped Lithium Niobate. The system comprises:

i) a laser that generates first and second laser beams;
ii) the first laser beam being a molten zone beam for melting the feed material and the second being an afterheater beam;
iii) two spaced apart wire electrodes situated on either side of the crystal rod parallel to the growth direction of the crystal rod, and connected to an alternating electrical current source which creates an electric field between the electrodes which is parallel then anti-parallel to the crystal rod growth axis;
iv) an Infra-Red scanner and computer controlled feedback system for controlling the axial and radial temperature gradients in the crystal rod in the region between the electrodes.

### FIELD OF THE INVENTION

The present invention describes a novel method for electric field poling of ferroelectric materials. It relates to providing periodic domains in crystals fabricated using the laser heated pedestal growth (LHPG) method and without the use of photolithography. In particular, the method of the present invention describes a way of forming periodic domains on a frequency doubling crystal that do not possess an undesired curvature relative to the crystal axis, thus ensuring maximum efficiency of nonlinear optical conversion by the crystal. This invention is related to the inventions described in co-pending, commonly assigned application Ser. Nos. 12/020,382 and 12/101,741 the disclosures of which are incorporated herein in their entirety by this reference.

### BACKGROUND OF THE INVENTION

Periodically poled crystals are commercially available products which are used as frequency (wavelength) converters for light such as that emitted by lasers. The demand for periodically poled materials is increasing as applications for miniature displays (e.g., cell phone projectors) are becoming increasingly popular. The miniature devices involved in these applications require the maximum achievable efficiency and brightness coupled with a small footprint. To provide this, the maximum frequency conversion efficiency by the nonlinear crystal is needed. A current technique to make periodically poled crystals involves processing a crystal so that its nonlinear coefficient (nonlinearity) is periodically reversed to form a grating in a direction transverse to the optical path. The prior art technique comprises applying an electric field across a wafer of ferroelectric material. This causes inversion of crystal domains in the ferroelectric material, which reverses the polarity and, consequently, the crystal nonlinearity. The periodicity is currently achieved by applying a metal mask/electrode structure corresponding to the desired pattern of poling to the wafer before applying the electric field. However, this prior art approach presents some significant disadvantages. High electric fields (e.g., ≧20 kV/mm.) are required for bulk domain reversal at room temperature, particularly in ferroelectrics with a high coercive field (such as Lithium Niobate). Unfortunately, compositional non-uniformities and defects, inherent to the prior art growth method for the crystals, are also present in commercially available both doped (e.g., with magnesium oxide) and un-doped materials. These non-uniformities tend to create refractive indices fluctuation, i.e. nonlinear coefficient variations, and can contribute to a significant decrease in the conversion efficiency of the poled crystal.

The laser heated pedestal growth (LHPG) technique as shown in FIGS. 1a and 1b is known in the art as a suitable process for fabricating single crystal fibers of high melting point materials such as Lithium Niobate (melting point ca. 1260° C.). This crucible-free technique enables the growth of homogeneous single crystals, thus facilitating maximum efficiency for nonlinear conversion. In this LHPG process, a seed crystal is dipped in a laser heated molten zone of a source rod of the same material. The seed is withdrawn from the molten zone, while the source rod is fed toward the molten zone so that, as the seed is withdrawn, a crystal fiber body is formed at a solidifying (crystalline) interface. The square root of the ratio of the pull rate of the crystal to the feed rate of the rod determines the average diameter of the growing crystal fiber rod. We deem the term crystallization interface to be the preferred term although in the prior art the terms molten interface, melting interface, or growth interface are sometimes used in lieu of crystallization interface, and indicate the same phenomenon.

Several ways have been previously explored to periodically pole crystals grown using the LHPG technique, as illustrated in FIGS. 1A and 1B (See also R. S. Feigelson, Springer Ser. Opt. Sci. 47 (1985) 129; R. S. Feigelson, J. Cryst. Growth 79 (1986) 669. U.S. Pat. No. 5,171,400; Foulon, et. al., Chemical Physics Letters 245 (1995) 555-560 and Brenier et al., Appl. Phys. 30 (1997) L37-L39) and U.S. Pat. Nos. 5,171,400 and 7,258,740. In one case, the domains were created by periodically interrupting the beam of the laser. However, the domains so created presented an 180° phase mismatch right in the middle of the crystal fiber as these domains have a tendency to spontaneously grow bi-domain, thus making only half of the crystal fiber useful for nonlinear optical conversion.

A solution to this problem was envisioned by Foulon et al (supra) by the use of electrodes to pole the growing crystal at the crystalline interface, as shown in FIG. 2. The result was a crystal fiber which was poled all the way through without manifesting significant phase mismatch. Unfortunately however, in this case the domains will tend to follow the thermal isotherm of the melt/crystal interface and thus exhibit an interface curvature as shown in FIG. 3. This unwanted phenomenon is due to three factors:

i) the existence of convections (called Marangoni convections) in the molten zone, which generate a curved (convex) crystallization interface
ii) the intrinsic properties of the grown crystal (e.g., Lithium Niobate, doped or undoped for example) whose melting point and Curie temperature are very close (Curie point no more than 200 C below the melting point)
iii) the use of a growth method (LHPG) exhibiting very high axial gradients (greater than 700 C/cm) in the vicinity of the crystallization interface.

A similar approach is described in U.S. Pat. No. 7,258,740 which also considers electric poling during growth but using the procedure described therein causes the domains to again follow the curvature of the crystallization interface. The problem with curved domains in comparison to straight domains is a significant loss of efficiency in nonlinear conversion (i.e., loss of periodicity) at the edges of the crystal.

FIG. 4 provides an explanation of the loss of efficiency for crystals with a curved domain structure as opposed to a structure with straight domains. For crystals with straight domains, the phase matching condition, and maximum efficiency are defined by the condition:

Δk=k^{2ω}−2k^{ω}−K=0

Wherein k^{ω}, k^{2ω} and K are vectors, ω denotes the wavelength of the light whose frequency is being doubled and k denotes the wave vector at frequency (wavelength) ω or 2ω. K=2πm/Λ, Λ is the period of periodic poling and m is the order of the Quasi-Phase-Matching.

If K is not collinear to k^{ω} in areas where the domains are curved, then k^{2ω} is not collinear to k^{ω} which thus leads to decreased conversion efficiency.

The present invention describes a way of creating periodic domains that do not exhibit significant curvature, by using in-situ poling in a modified LHPG setup.

### DESCRIPTION OF THE DRAWINGS

FIGS. 1a and 1b illustrate the laser heated pedestal growth (LHPG) technique for fabricating single crystal fibers of high melting materials

FIG. 2 illustrates a prior art technique used to periodically pole single crystals fabricated using the LHPG technique

FIG. 3 shows the curved domains which result from poling in accordance with FIG. 2

FIG. 4 illustrates why the frequency conversion efficiency is significantly reduced when the domains are curved

FIG. 5 illustrates schematically an apparatus suitable for producing crystals using the LHPG method which apparatus includes an after heater which, in conjunction with the enhancements of the present invention, permits fabrication of crystals which provide coplanar domains which are substantially parallel to the fiber axis

FIG. 6 illustrates the location of the poling electrodes partially encompassing the afterheater zone when practicing the present invention

FIG. 7 is a graph which shows the temperature in a 1 mm diameter fiber crystal of Lithium Niobate as it is drawn away from the crystallization interface surface without using the after heater shown in FIG. 5. In this graph, z=0 indicates the location of the crystallization interface surface and that the Curie temperature is reached at ˜0.1 mm above the crystallization interface.

FIG. 8 illustrates the direction of the Marangoni convections in the molten zone when the crystal is fabricated using the apparatus of FIG. 5

FIG. 9 is a graph which shows the temperature in a fiber crystal of Lithium Niobate as a function of distance from the crystallization interface when using the apparatus of FIG. 10 (with and without use of the after-heater) relative to the Curie temperature. As can be seen the fiber crystal is maintained substantially at the Curie temperature (point) in excess of 0.5 mm. beyond the crystalline interface.

FIG. 10 is a schematic of the apparatus of FIG. 5 modified in accordance with the present invention by the addition of an infrared scanner (camera) linked to a computer. The shape of the crystallization interface is visualized by the scanner and deviation of the poling domains as perceived by the scanner relative to a flat domain interface is corrected by means of a feedback loop which changes the position of the attenuator (a waveplate whereby each setting only lets a portion of the polarized laser beam go through) and thereby adjusts the power of the afterheater.

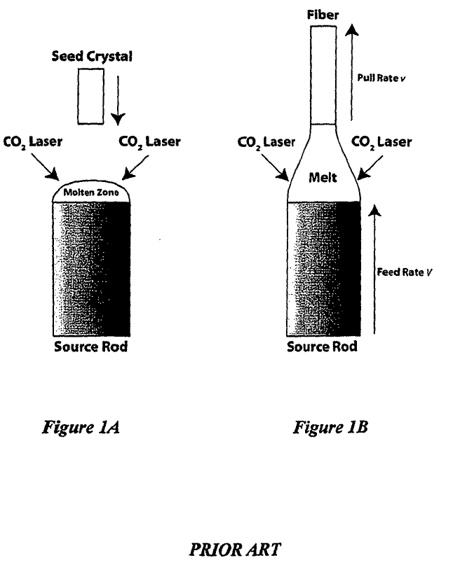

### DESCRIPTION OF THE INVENTION

The present invention results from the need to make periodically poled devices with high conversion efficiency. The approach described herein overcomes the drawbacks of previous methods which used the LHPG method to grow in situ periodically poled crystal fibers. A significant advantage of the present invention over the prior art methods is that it is applicable to poling at the time a ferroelectric crystalline body is being formed. Moreover, the ability to pole at temperatures close to the Curie point of the crystal (where the coercive field is or approaches zero) facilitates periodic poling and does not require the use of complicated photolithography processes. In addition, the method of the present invention achieves a uniform and regular periodic polarization inversion structure substantially perpendicular to the crystal axis.

The LHPG technique is advantageous for the purpose of fabricating frequency doubling crystals as it allows one to grow the crystals exhibiting the best uniformity in composition, which in turn can translate into the best homogeneity in refractive index and therefore provide the best nonlinear optical conversion efficiency. However, as already indicated, one of the drawbacks of prior art methods which combined LHPG with periodic poling is that the domains tend to follow the curvature of the crystallization interface and this phenomenon significantly decreases the conversion efficiency. The purpose of the present invention is to create poling domains substantially parallel to each other and perpendicular to the crystal's long (growth) axis in a periodically poled crystal grown using the LHPG technique.

An advantage of the present invention is that it enables one to obtain substantially homogenous, periodically poled nonlinear optical crystals grown by the LHPG technique but which do not exhibit undesirable curvature of the domain interfaces. Suitable ferroelectric materials for the present invention include Lithium Niobate (both congruent and stoichiometric), Lithium Niobate (both congruent and near stoichiometric), doped with MgO, Sc₂O₃ or Yb₂O₃ and also other crystalline materials having a melting point in the range of 1000° to 2000° C. and whose Curie temperature is no greater than 200° C. below its melting point. At the Curie temperature of a ferroelectric material, the coercive field nears zero. This means that domain reversal is readily achieved, with an electric field as low as a few hundred volts per centimeter. The LHPG method presents a unique possibility to periodically reverse the domains in situ during growth, by applying a relatively low electric field (300 to 500, preferably 350 to 450V/cm) at the Curie temperature. This works well with Lithium Niobate (melting point=1253° C. and Curie point=1142° C.) but is ineffective, for example, in the case of Lithium Tantalate (melting point=1560° C. and Curie point=600° C.). A possible explanation for this is that the conductivity of air at 600° C. is not high enough to permit the alternating electric field to pass between the electrodes and thereby through the crystal situated so as to reverse the domains.

### Example

A CO₂ laser beam is focused onto the end of a source rod containing the desired crystalline material which can in some cases includes dopant (e.g., Lithium Niobate or MgO doped Lithium Niobate), by means of circularly symmetric laser optics as taught in co-pending, commonly assigned US Patent Application PCT US2008/052084, the entire teaching of which is incorporated herein by this reference, thereby producing a homogeneous circular distribution of laser radiation on the source rod. When the melting temperature is reached at the tip of the source rod, thereby forming a molten zone, a seed (single crystal or sintered rod, preferably of the same crystalline material) but of smaller diameter than the source rod is immersed into the molten zone. The fiber which solidifies as the seed is withdrawn from the molten zone forms as a single crystal. The source rod is fed into the molten zone at a rate so as to maintain a constant melt volume. As previously explained the ratio of fiber pulling rate and source rod pushing rate determines the diameter of the crystal fiber.

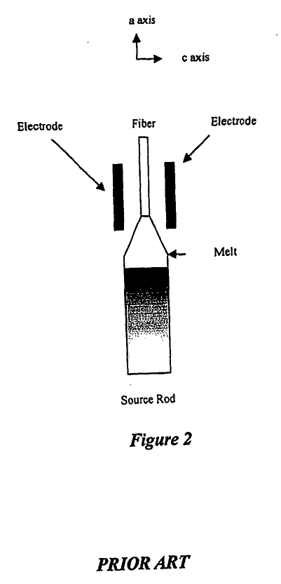

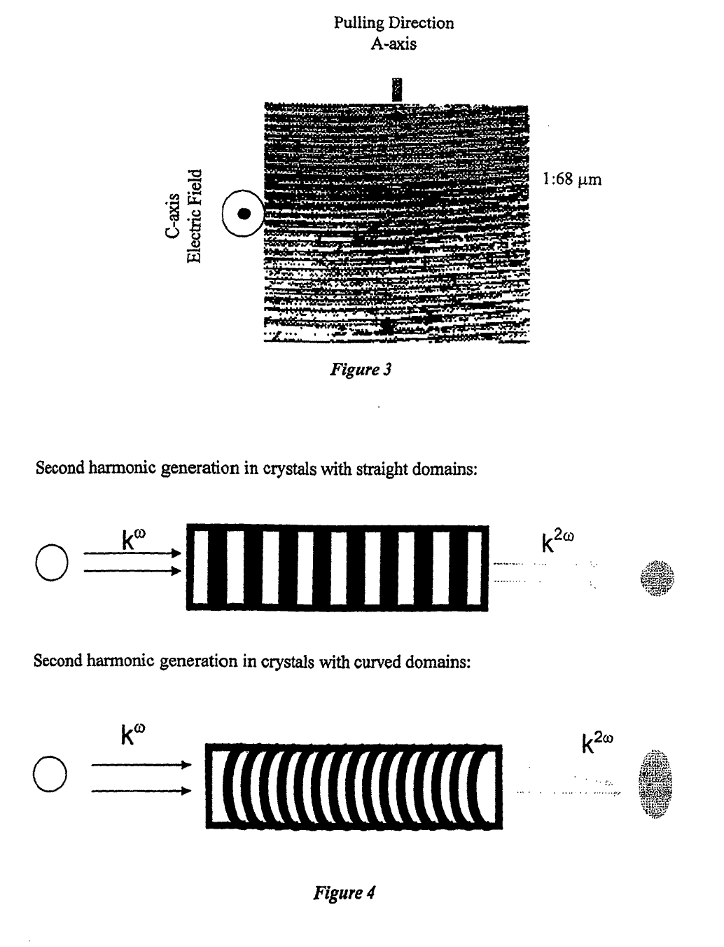

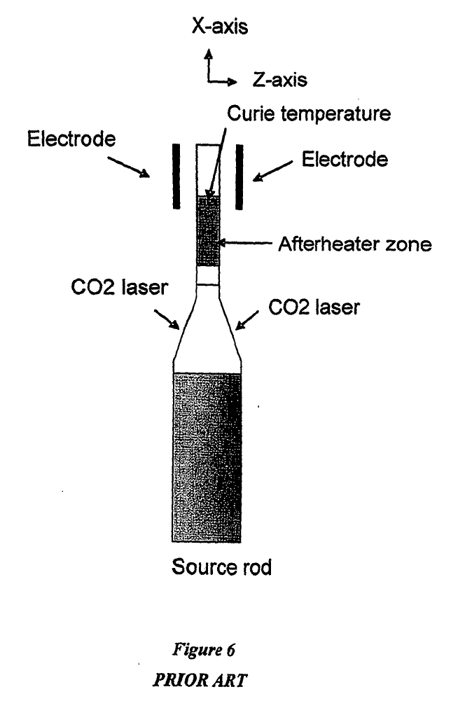

The present invention involves use of both an after heater and in situ poling. As indicated, the method of the present invention is particularly advantageous with respect to materials (such as Lithium Niobate or MgO-doped Lithium Niobate), and other crystalline materials having a Curie temperature very close to the material's melting point i.e., preferably no more than 200° below the melting point. The poling is effected by means of two tungsten electrodes of approximately 250 micron diameter situated parallel to the crystal growth direction and spaced approximately 6 mm apart as shown in FIGS. 2 and 6. The electrodes are connected to an alternating current electricity generator (˜350 Volts) to thereby create an electric field parallel and then anti-parallel to the crystal rod growth axis.

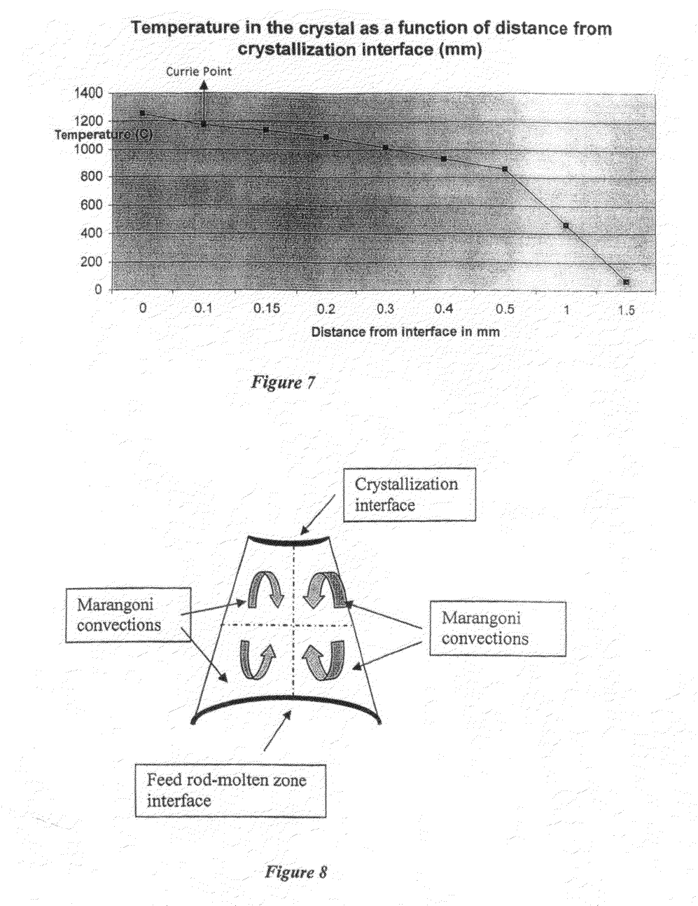

The graph in FIG. 7 shows the temperature in a 1 mm diameter fiber crystal of Lithium Niobate as it is drawn away from the crystallization interface. In this graph, z=0 (zero on the x axis) denotes the crystallization interface. As shown in FIG. 7, the Curie temperature is reached at ˜0.1 mm above the crystallization interface. In this situation, it has been observed that if the poling electrodes are placed as shown in FIG. 2 the poling domains follow the curved shape of the crystallization interface, which exhibits a curvature because of the Marangoni convections present in the melt.

One of the characteristics of the LHPG method is that the growth crystallization interface is curved. This is due to the convection cells that are found in the molten zone. In the LHPG method, the predominant convections in the molten zone are Marangoni convections as shown in FIG. 8. These convections are due to the temperature difference between the center of the molten zone, the air-molten zone boundaries, the molten zone-crystal interface and the molten zone-feed rod interface. The Marangoni convection currents in the molten zone (as shown in FIG. 8) are responsible for the curvature of the solid-liquid interfaces. The Marangoni currents are the reason for the radial gradient at the growth crystallization interface.

The radius of curvature R of the crystallization interface is given by the following equation:

$$R = ( \frac{r}{\frac{\partial T}{\partial r}} ) ( \frac{\partial T}{\partial z} )$$

In this equation r denotes the crystal radius, T is the temperature of the crystal and z is the height above the crystallization interface. At the vicinity of the interface, we can consider the axial gradient

$$( \frac{\partial T}{\partial z} )$$

a constant.

For a straight line, the radius of curvature is, of course, infinite. For a crystal of fixed diameter, R tends towards infinity when

$$\frac{\partial T}{\partial r}$$

(the radial gradient) tends towards 0.

Unfortunately, in a situation of growth by LHPG using the techniques of the prior art with a crystal like Lithium Niobate, whose melting point and Curie temperature only differ by about 100° C., the crystallization interface and the Curie isotherm are in such close proximity that the shape of the ferroelectric domains follows the curvature of the crystallization interface.

The present invention provides a unique solution to avoid this problem. I have found there are two approaches to making the domains flatter:
i) Make the crystallization interface flatter: i.e., decrease the radial gradient and thus the magnitude of the Marangoni convections in the melt, and
ii) Move the Curie isotherm away from the crystallization interface: this can be achieved by decreasing the axial temperature gradient. If it is farther away from the molten zone, the Curie isotherm will not be subjected to the curvature created by the Marangoni convections.

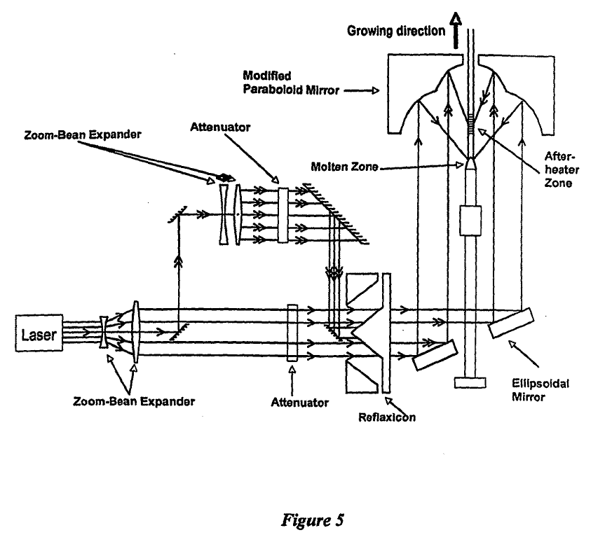

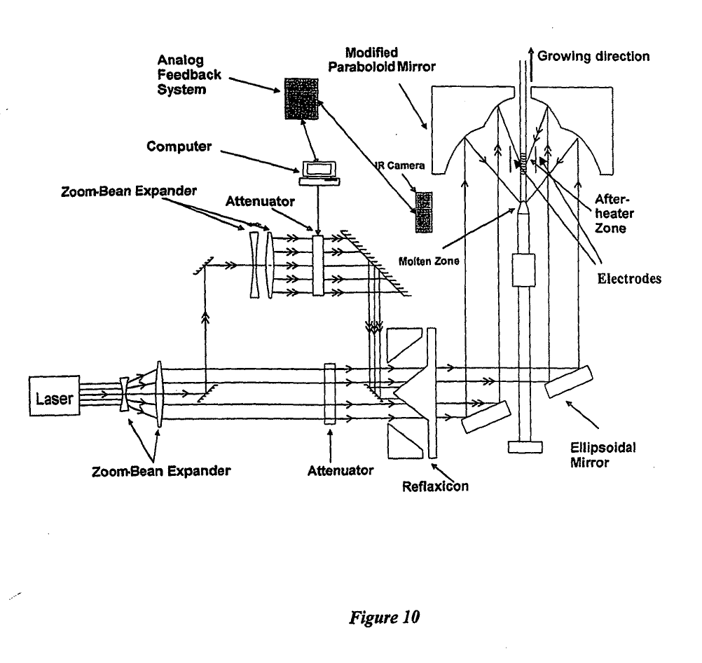

Further details of the process of the present invention are as follows: the LHPG apparatus is similar to the one described in US Patent Application PCT/US2008/052084 (which apparatus includes a laser afterheater), as illustrated in FIG. 5. However, in the present invention the LHPG apparatus further includes essential additional components (i.e., an Infra-Red scanner (camera) and computer controlled feedback system) as described below and shown in FIG. 10. In growing the crystals in accordance with the present invention the radial temperature gradient of the growing crystal is decreased in a controlled fashion by the use of an optical after heater. Poling electrodes are placed as shown in FIG. 6. The tip of the ceramic rod (preferably made of the material used to grow the crystal, e.g. Lithium Niobate) is melted by the laser such as a CO₂ laser and the Lithium Niobate seed is dipped into the molten zone. After the rod-molten zone-seed is temperature stabilized (i.e., there is no more observable variations of height and width of the molten zone), the after heater is turned on. The power coming to the zone heated by the after heater is controlled by the setting of the attenuator (a waveplate whereby each setting only lets a selected portion of the polarized laser beam go through). The shape of the crystallization interface is visualized by an infrared scanner (as shown in FIG. 10) linked to a computer and feedback system. The deviation from a flat interface, i.e., the curvature seen by the Infra-Red scanner is corrected by means of a feedback loop which changes the position of the attenuator and consequently adjusts the power of the afterheater. The feedback is based on the visualization, via the IR scanner, of the temperature difference between the middle (Tm) of the interface and the extremities (Te), that is, the temperature of the outer surface of the crystal rod. The afterheater power is increased until Tm=Te. The crystal is then pulled through the electrodes in the alternating current electric field at a speed that is in correlation with the desired domain period. As shown in FIG. 6 the poling electrodes are placed so as to ensure that the alternating electric field passes through the crystal i.e. is applied to the crystal when it is at the Curie temperature.

The spatial (distance between domains) poling period Λ for a crystal is twice the coherence length lc:

Λ=2l_{c}.

If V is the speed at which the crystal is being pulled, then Λ is linked to the time period T by:

Λ=TV

For example, to get a coherence length of 6.8 μm in Mg doped LiNbO₃, a pulling speed of 120 mm/h and a time period of 204 ms for the alternating field are required.

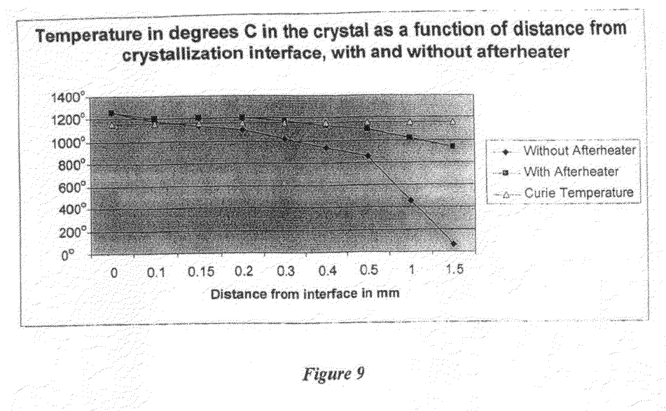

The afterheater will cause the temperature of the molten zone-air interface to rise and thereby reduce the radial temperature gradient in the growing crystal to near zero. The flattening of the radial gradient will decrease or even eliminate the Marangoni convections and thereby tend to make the crystallization interface flatter. The axial temperature gradient will also decrease (since the crystal is heated by the afterheater as it comes out of the molten zone) and the flattening of the axial gradient will move the Curie isotherm farther away from the crystallization interface, as illustrated in FIG. 9. These two phenomena are synergistic to each other since the combination of these two effects will lead to flat ferroelectric domains and thus increased nonlinear optical conversion efficiency. The flattening of the domain interface is thus the result of two interrelated phenomena: i) moving the Curie interface farther away from the crystallization interface, and ii) reducing the radial and axial temperature gradients. The infra-red scanner control of the afterheater accomplishes both phenomena.

1. A laser heated pedestal growth system for growing a single crystal rod from a crystalline ferroelectric feed material having a Curie temperature no more than 200° C. below its melting point, said system comprising:
i) a laser that generates a first laser beam;
ii) a bifocal mirror positioned optically downstream of the first laser beam, said first laser beam being transformed into a molten zone beam and a second afterheater beam, the bifocal mirror including a first focusing zone and a second focusing zone, the first focusing zone directing the molten zone beam to melt the feed material at a crystalline interface to the single crystal rod, and the second focusing zone directing the afterheater beam to an afterheater region of the single crystal rod;
iii) two spaced apart electrodes situated on either side of the crystal rod and parallel to the growth direction of the crystal rod, said electrodes being connected to an alternating electrical current generator for creating an electric field between said electrodes which field is parallel and then anti-parallel to the crystal rod growth axis, with said afterheater region being situated at least partially between said electrodes;
and iv) an Infra-Red scanner and computer controlled feedback system for controlling the axial and radial temperature gradients in the crystal rod in the region between the electrodes.

2. The laser heated pedestal growth system of claim 1 further comprising: a first mirror positioned optically between the laser and the bifocal mirror, the first mirror deflecting a central portion of the first laser beam to thereby form a circular laser beam and an annular laser beam, one of the circular laser beam and the annular laser beam being the molten zone beam and the other being the afterheater beam; and a second mirror that optically realigns the molten zone beam and the afterheater beam.

3. The system of claim 1 wherein the laser is a CO₂ laser.

4. The system of claim 1 wherein the laser is programmed to cause the afterheater beam to maintain the crystal rod substantially at its Curie temperature for at least 0.5 mm beyond the crystalline interface.

5. The laser heated pedestal growth system of claim 1 further comprising an optical attenuator that adjusts an optical power of the afterheater beam.

6. The laser heated pedestal growth system of claim 1 wherein said feed material comprises Lithium Niobate.

7. The laser heated pedestal growth system of claim 5 wherein said feed material comprises MgO doped Lithium Niobate.

8. The laser heated pedestal growth system of claim 1 wherein said alternating electrical current generator produces an electric field of 300 to 500V/cm.

9. The laser heated pedestal growth system of claim 1 wherein said feed material has a melting point in the range of 1000° C. and 2000° C. and whose Curie temperature is no greater than 200° C. below said melting point
